(19) United States
(12) Patent Application Publication
(10) Pub. No.: US 2026/0282751 A1
(43) Pub. Date: Sep. 17, 2026

(54) PIEZOELECTRIC LAMINATE, PIEZOELECTRIC ELEMENT, AND METHOD FOR MANUFACTURING PIEZOELECTRIC LAMINATE

(71) Applicant: AGC Inc., Tokyo (JP)

(72) Inventors: Kenichi UMEDA, Tokyo (JP); Yuki AOSHIMA, Tokyo (JP)

(73) Assignee: AGC Inc., Tokyo (JP)

(21) Appl. No.: 19/664,817

(22) Filed: Apr. 30, 2026

Related U.S. Application Data
(63) Continuation of application No. PCT/JP2024/038309, filed on Oct. 28, 2024.

(30) Foreign Application Priority Data
Nov. 1, 2023 (JP) 2023-187764

(51) Int. Cl. H10N 30/00; H10N 30/06; H10N 30/079; H10N 30/853; H10N 30/87

(52) U.S. Cl. CPC H10N 30/708; H10N 30/06; H10N 30/079; H10N 30/853; H10N 30/87

(57) ABSTRACT

A piezoelectric laminate, including: a substrate; and a laminated film provided on at least one surface of the substrate, in which the laminated film includes, in order from a substrate side, a first base layer, an electrode layer, and a piezoelectric thin film layer, the first base layer is in contact with the electrode layer, and the first base layer contains a nitrogen compound containing at least one element selected from the group consisting of Group III to VI elements.

### CROSS-REFERENCE TO RELATED APPLICATIONS

This is a continuation of International Application No. PCT/JP2024/038309 filed on Oct. 28, 2024, and claims priority from Japanese Patent Application No. 2023-187764 filed on Nov. 1, 2023, the entire content of which is incorporated herein by reference.

### TECHNICAL FIELD

The present invention relates to a piezoelectric laminate, a piezoelectric element, and a method for manufacturing the piezoelectric laminate.

### BACKGROUND ART

In recent years, micro electro mechanical systems (MEMS) have attracted attention. The MEMS is a device in which mechanical element components, electronic circuits, and the like are integrated on a single substrate by a micromachining technique. In MEMS having functions of a sensor, a filter, a harvester, an actuator, or the like, a piezoelectric laminate or a piezoelectric element having the piezoelectric laminate is used.

The piezoelectric laminate is formed by providing a thin film (hereinafter, also abbreviated as piezoelectric thin film layer) made of a substance having orientation (for example, aluminum nitride) on a substrate such as silicon (Si), sapphire, or glass. The piezoelectric thin film has piezoelectric properties and pyroelectric properties due to the orientation, and is applied as a sensor, a component of a piezoelectric thin film resonator or MEMS, or the like.

In order to enhance the piezoelectric performance of the piezoelectric thin film, it is important that the piezoelectric thin film layer has high orientation. In order to obtain a piezoelectric thin film layer having high orientation, many studies have been made. For example, Patent Literatures 1 and 2 disclose that c-axis orientation is improved by providing a base layer of tungsten or platinum between a silicon substrate or a glass substrate and aluminum nitride. Patent Literature 3 discloses that good crystallinity can be obtained by using an aluminum nitride base layer having a crystal of the same hexagonal wurtzite structure.

### CITATION LIST

### Patent Literature

Patent Literature 1: JP2004-6535A
Patent Literature 2: JP2004-265899A
Patent Literature 3: JP2019-145677A

### SUMMARY OF INVENTION

### Technical Problem

However, in order to improve crystalline orientation by a method in the related art, an electrode layer in contact with a piezoelectric thin film layer has the same crystal structure, or lattice matching is required, and there is a limitation on selection of an electrode material constituting the electrode layer.

The present invention has been made in view of the above problems, and an object of the present invention is to improve crystalline orientation of a piezoelectric thin film layer.

### Solution to Problem

The present inventors have found that the above problems can be solved by providing a base layer containing a nitrogen compound containing at least one element selected from the group consisting of Group III to VI elements between a substrate and an electrode layer, and have completed the present invention.

That is, one embodiment of the present invention relates to the following.
1. A piezoelectric laminate, including:
a substrate; and
a laminated film provided on at least one surface of the substrate, in which
the laminated film includes, in order from a substrate side, a first base layer, an electrode layer, and a piezoelectric thin film layer,
the first base layer is in contact with the electrode layer, and
the first base layer contains a nitrogen compound containing at least one element selected from the group consisting of Group III to VI elements.
2. The piezoelectric laminate according to 1, in which
the piezoelectric thin film layer contains aluminum nitride, and
the aluminum nitride has a hexagonal wurtzite structure oriented in a c-axis direction.
3. The piezoelectric laminate according to 2, in which
the aluminum nitride has a half width at a peak of a (002) plane measured by an X-ray diffraction method being 0.34 or less.
4. The piezoelectric laminate according to 1, in which
the first base layer has a sodium chloride structure, a fluorite structure, or a perovskite structure.
5. The piezoelectric laminate according to 1, in which
the first base layer contains a nitrogen compound containing at least one element selected from the group consisting of Group III to V elements.
6. The piezoelectric laminate according to 1, in which
the first base layer is a nitrogen compound containing at least one element selected from Zr, Hf, Y, W, and Nb.
7. The piezoelectric laminate according to 1, in which
the first base layer contains a nitrogen compound represented by a chemical formula QN_{X},
Q in the chemical formula is at least one element selected from the group consisting of Group III to VI elements, and
a nitriding degree represented by x in the chemical formula satisfies 1<x<2.
8. The piezoelectric laminate according to 7, in which
the nitriding degree represented by x in the chemical formula satisfies 1.1<x<1.65.
9. The piezoelectric laminate according to 1, in which
the first base layer has a thickness of 0.2 nm or more and 100 nm or less.
10. The piezoelectric laminate according to 9, in which
the first base layer has the thickness of 0.4 nm or more and 80 nm or less.
11. The piezoelectric laminate according to 1, in which
the piezoelectric thin film layer has an arithmetic average roughness (Ra) of 3.0 nm or less.
12. The piezoelectric laminate according to 1, further including:
a second base layer, in which
the second base layer is in contact with the electrode layer and the piezoelectric thin film layer, and
the second base layer contains a nitrogen compound containing at least one element selected from the group consisting of Group III to VI elements.
13. The piezoelectric laminate according to 12, in which
the second base layer has a thickness of 0.2 nm or more and 40 nm or less.
14. The piezoelectric laminate according to 1, in which
the piezoelectric thin film layer has a film thickness of 100 nm or more and 10 μm or less.
15. A piezoelectric element including the piezoelectric laminate according to any one of 1 to 14.
16. A method for manufacturing a piezoelectric laminate, the piezoelectric laminate including a substrate and a laminated film provided on at least one surface of the substrate, the method including:
preparing the substrate; and
forming a first base layer, an electrode layer, and a piezoelectric thin film layer on at least one surface of the substrate in this order, in which
the first base layer contains a nitrogen compound containing at least one element selected from the group consisting of Group III to VI elements, and
the electrode layer is formed so as to be in contact with the first base layer.
17. A method for manufacturing a piezoelectric laminate, the piezoelectric laminate including a substrate and a laminated film provided on at least one surface of the substrate, the method including:
preparing the substrate; and
forming a first base layer, an electrode layer, a second base layer, and a piezoelectric thin film layer on at least one surface of the substrate in this order, in which
the first base layer contains a nitrogen compound containing at least one element selected from the group consisting of Group III to VI elements,
the second base layer contains a nitrogen compound containing at least one element selected from the group consisting of Group III to VI elements, and
the electrode layer is formed so as to be in contact with the first base layer.
18. The method for manufacturing a piezoelectric laminate according to 16 or 17, in which
the piezoelectric thin film layer contains aluminum nitride, and
the aluminum nitride has a hexagonal wurtzite structure oriented in a c-axis direction.

### Advantageous Effects of Invention

According to the present invention, the crystalline orientation of the piezoelectric thin film layer can be improved.

### BRIEF DESCRIPTION OF DRAWINGS

FIG. 1 is a schematic cross-sectional view of a piezoelectric laminate according to one embodiment of the present invention.

FIG. 2 is a schematic cross-sectional view of a piezoelectric laminate according to one embodiment of the present invention.

### DESCRIPTION OF EMBODIMENTS

Hereinafter, a content of an embodiment of the present invention will be described with reference to the embodiment. However, the present invention includes many different aspects, and should not be construed as being limited to the content of the embodiment exemplified below.

A first embodiment of the present invention is a piezoelectric laminate, including: a substrate; and a laminated film provided on at least one surface of the substrate, in which the laminated film includes, in order from a substrate side, a first base layer, an electrode layer, and a piezoelectric thin film layer,
the first base layer is in contact with the electrode layer, and
the first base layer contains a nitrogen compound containing at least one element selected from the group consisting of Group III to VI elements.

A second base layer may be provided between the electrode layer and the piezoelectric thin film layer.

A second embodiment of the present invention is a method for manufacturing a piezoelectric laminate, the piezoelectric laminate including a substrate and a laminated film provided on at least one surface of the substrate, the method including: preparing the substrate; and forming a first base layer, an electrode layer, and a piezoelectric thin film layer on at least one surface of the substrate in this order, in which the first base layer contains a nitrogen compound containing at least one element selected from the group consisting of Group III to VI elements, and the electrode layer is formed so as to be in contact with the first base layer.

A third embodiment of the present invention is a method for manufacturing a piezoelectric laminate, the piezoelectric laminate including a substrate and a laminated film provided on at least one surface of the substrate, the method including: preparing the substrate; and forming a first base layer, an electrode layer, a second base layer, and a piezoelectric thin film layer on at least one surface of the substrate in this order, in which the first base layer contains a nitrogen compound containing at least one element selected from the group consisting of Group III to VI elements, the second base layer contains a nitrogen compound containing at least one element selected from the group consisting of Group III to VI elements, and the electrode layer is formed so as to be in contact with the first base layer.

Embodiments of the present invention (hereinafter, also abbreviated as the present embodiment) include the first to third embodiments.

The method for manufacturing a piezoelectric laminate according to the second embodiment corresponds to a configuration example of the piezoelectric laminate of the first embodiment in which the piezoelectric laminate does not include the second base layer, and the method for manufacturing a piezoelectric laminate according to the third embodiment corresponds to a configuration example of the piezoelectric laminate of the first embodiment in which the piezoelectric laminate includes the second base layer.

### <Piezoelectric Laminate>

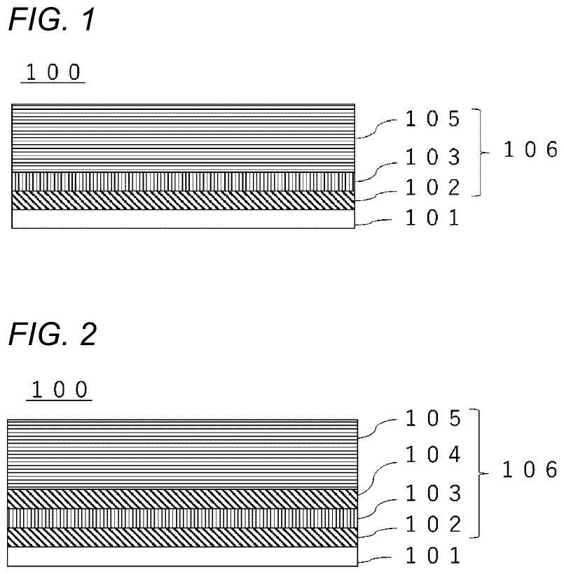

A structure and a manufacturing method of a piezoelectric laminate 100 according to the present embodiment will be described with reference to FIG. 1.

### [Structure of Piezoelectric Laminate]

FIG. 1 is a schematic cross-sectional view illustrating the structure of the piezoelectric laminate 100 according to the present embodiment. As illustrated in FIG. 1, the piezoelectric laminate 100 includes a substrate 101 and a laminated film 106 provided on at least one surface of the substrate 101. The laminated film 106 includes, in order from a substrate 101 side, a first base layer 102, an electrode layer 103, and a piezoelectric thin film layer 105. Here, the first base layer 102 and the electrode layer 103 are in contact with each other.

### (Substrate)

A thickness, a material, and the like of the substrate 101 are not particularly limited as long as the laminated film 106 can be formed on the surface of the substrate 101, and any material known in the related art can be used. Examples of the substrate 101 include: a substrate obtained by forming silicon, diamond, or another polycrystalline film on a surface of a substrate such as silicon (Si) single crystal; a metal substrate such as stainless steel (SUS); an amorphous substrate such as glass; and a film such as polyethylene terephthalate (PET), polycarbonate (PC), a cycloolefin polymer, polyimide, or polyethylene naphthalate (PEN).

### (First Base Layer)

The first base layer 102 is a layer formed directly or via another layer on at least one surface of the substrate 101, and improves crystalline orientation of the piezoelectric thin film layer 105.

A base (for example, substrate 101 or first base layer 102) of the piezoelectric thin film layer 105 affects the crystalline orientation of the piezoelectric thin film layer 105. The base is affected by surface contamination due to a natural oxide film or carbon-based contaminants even after a cleaning process or the like, so that crystalline orientation of substances constituting the piezoelectric thin film layer 105 are likely to be non-uniform. In contrast, the present inventors have found that a polarity of the piezoelectric thin film layer 105 can be controlled and the crystalline orientation of the piezoelectric thin film layer 105 can be improved by providing the first base layer 102 containing a nitrogen compound containing at least one element selected from the group consisting of Group III to VI elements below the electrode layer 103.

Thus, by improving the crystalline orientation of the piezoelectric thin film layer 105, the piezoelectric performance can be effectively improved. In particular, when the first base layer 102 is formed under an atmosphere having 100% of nitrogen, it is easy to obtain a crystal structure in which nitrogen is incorporated in an amount excessively larger than a stoichiometric ratio, and the aforementioned effect can be further promoted.

The first base layer 102 contains the nitrogen compound containing at least one element selected from the group consisting of Group III to VI elements. The nitrogen compound containing at least one element selected from the group consisting of Group III to VI elements is represented by a chemical formula QN_{X}, and in the chemical formula, Q represents at least one element selected from the group consisting of Group III to VI elements, and x represents a nitriding degree. The nitriding degree x is more than 0, preferably more than 1, more preferably more than 1.1, and further preferably more than 1.2. In addition, the nitriding degree x is preferably less than 2, more preferably less than 1.65, and further preferably less than 1.5. By setting the nitriding degree x within the above range, c-axis orientation of the piezoelectric thin film layer is further improved. This effect is remarkable when the piezoelectric thin film layer contains aluminum nitride.

The nitriding degree x can be identified by a Rutherford backscattering spectrometry (RBS) method. Further, in a case where there are a plurality of samples, the nitriding degree x for two or more samples may be measured by the above RBS method and ellipsometry, respectively, and a correlation coefficient thereof is derived, and thereafter, the nitriding degree x by the RBS method for other samples may be calculated based on a measurement result by ellipsometry.

In the present embodiment, the nitrogen compound contained in the first base layer 102 is a nitride, but the nitrogen compound does not necessarily need to have a stoichiometric ratio, and may be in an overnitrided (metastable) state. In the present embodiment, it is preferable that the nitrogen compound constituting the first base layer 102 is cubic and has a (111) plane main orientation, and is capable of taking the overnitrided state (metastable state). By using such a nitrogen compound, the piezoelectric thin film layer 105 is complemented with nitrogen, the polarities of the substances constituting the piezoelectric thin film layer 105 can be easily unified, and the crystalline orientation can be easily improved.

In the present embodiment, examples of the Group III to VI elements contained in the nitrogen compound constituting the first base layer 102 include scandium (Sc), yttrium (Y), titanium (Ti), zirconium (Zr), hafnium (Hf), rutherfordium (Rf), vanadium (V), niobium (Nb), tantalum (Ta), dubnium (Db), chromium (Cr), molybdenum (Mo), tungsten (W), and seaborgium (Sg). Among nitrogen compounds containing these, Zr, Hf, Y, W, and Nb are preferable from the viewpoint of being cubic and having a (111) plane main orientation, and being capable of taking the overnitrided state (metastable state). In the present embodiment, the nitrogen compound constituting the first base layer 102 is preferably ZrN, Zr₃N₄, HAN, YN, Y₅N₁₄, WN, W₇N₁₂, NbN, and Nb₂N₃, and more preferably ZrN and Zr₃N₄. These nitrogen compounds may be used alone or in combination of two or more thereof.

In the present embodiment, the first base layer 102 preferably has a (111) plane preferential orientation structure that is preferentially oriented in a (111) plane direction, but may not necessarily be (111) plane-preferentially oriented. With the (111) plane preferential orientation structure, lattice matching with the piezoelectric thin film layer 105 is improved, so that the crystalline orientation of the piezoelectric thin film layer 105 can be further improved.

In the present embodiment, it is preferable that the first base layer 102 has a sodium chloride structure, a fluorite structure, or a perovskite structure. With the above structure, preferential orientation in the (111) plane direction is easily achieved, so that crystalline orientation of the outermost layer of the piezoelectric thin film layer 105 can be further improved.

A film thickness of the first base layer is not particularly limited, and is preferably 0.2 nm or more, and more preferably 0.4 nm or more, from the viewpoint of stably forming a continuous film and further enhancing the c-axis orientation of the piezoelectric thin film layer. In addition, from the viewpoint of industrially increasing the film formation efficiency and from the viewpoint of preventing a continuous film from being lost due to generation of cracks or the like, the film thickness of the first base layer is preferably 100 nm or less, more preferably 80 nm or less, and further preferably 60 nm or less.

### (Electrode Layer)

A material of the electrode layer 103 is not particularly limited, and an electrode layer commonly used for the piezoelectric laminate 100 can be used. The electrode layer 103 is in direct contact with the first base layer 102. As an electrode material constituting the electrode layer 103, for example, a film containing a metal material such as aluminum (Al), a transition metal such as molybdenum (Mo), titanium (Ti), chromium (Cr), tantalum (Ta), iridium (Ir), or nickel (Ni), a noble metal such as ruthenium (Ru), palladium (Pd), platinum (Pt), gold (Au), silver (Ag), or copper (Cu), a conductive metal oxide such as ruthenium oxide (RuO₂), or a conductive metal nitride such as chromium nitride (CrN) is used. In addition, the above materials may be combined to form the electrode layer 103.

A film thickness of the electrode layer 103 is not particularly limited, and is preferably 5 nm or more from the viewpoint of forming a continuous film, for example. In addition, from the viewpoint of preventing the continuous film from being lost due to generation of cracks or the like, the film thickness of the electrode layer 103 is preferably 1,000 nm or less.

An arithmetic average roughness (Ra) of the electrode layer 103 is not particularly limited, and is preferably 0.1 nm or more, for example, from the viewpoint of obtaining good electrical conductivity due to the presence of crystal grains. In addition, from the viewpoint of preventing a reduction in electrical conductivity due to grain boundary scattering, the above arithmetic average roughness (Ra) is preferably 10 nm or less.

A specific electrical resistance of the electrode layer 103 is preferably 1×10 Ω·cm or less, and particularly preferably 1×10⁻² Ω·cm or less, from the viewpoint of ensuring good conductivity. A lower limit of the above specific electrical resistance is not particularly limited, and is usually 1×10⁻⁶ Ω·cm or more. The specific electrical resistance of the electrode layer 103 can be measured by using a Hall effect measuring device for a substrate on which the electrode layer 103 is formed.

### (Second Base Layer)

In the present embodiment, a second base layer 104 is not essential, but may be provided between the electrode layer 103 and the piezoelectric thin film layer 105. The second base layer improves the crystalline orientation of the piezoelectric thin film layer. FIG. 2 illustrates a configuration example of the piezoelectric laminate 100 in which the second base layer 104 is provided between the electrode layer 103 and the piezoelectric thin film layer 105.

When the second base layer 104 is formed under an atmosphere of 100% of nitrogen, it is easy to obtain a crystal structure in which nitrogen is incorporated in an amount excessively larger than a stoichiometric ratio, and the aforementioned effect can be further promoted.

The second base layer 104 contains the nitrogen compound containing at least one element selected from the group consisting of Group III to VI elements. The nitrogen compound containing at least one element selected from the group consisting of Group III to VI elements is represented by a chemical formula QN_{X}, and in the chemical formula, Q represents at least one element selected from the group consisting of Group III to VI elements, and x represents a nitriding degree. The nitriding degree x is more than 0, preferably more than 1, more preferably more than 1.1, and further preferably more than 1.2. In addition, the nitriding degree x is preferably less than 2, more preferably less than 1.65, and further preferably less than 1.5. By setting the nitriding degree x within the above range, c-axis orientation of the piezoelectric thin film layer is further improved. This effect is remarkable when the piezoelectric thin film layer contains aluminum nitride.

In the present embodiment, the nitrogen compound contained in the second base layer 104 is a nitride, but the nitrogen compound does not necessarily need to have a stoichiometric ratio, and may be in an overnitrided (metastable) state. In the present embodiment, it is preferable that the nitrogen compound constituting the second base layer 104 is cubic and has a (111) plane main orientation, and is capable of taking the overnitrided state (metastable state). By using such a nitrogen compound, the piezoelectric thin film layer 105 is complemented with nitrogen, the polarities of the substances constituting the piezoelectric thin film layer 105 can be easily unified, and the crystalline orientation can be easily improved.

In the present embodiment, examples of the Group III to VI elements contained in the nitrogen compound constituting the second base layer 104 include scandium (Sc), yttrium (Y), titanium (Ti), zirconium (Zr), hafnium (Hf), rutherfordium (Rf), vanadium (V), niobium (Nb), tantalum (Ta), dubnium (Db), chromium (Cr), molybdenum (Mo), tungsten (W), and seaborgium (Sg). Among nitrogen compounds containing these, Zr, Hf, Y, W, and Nb are preferable from the viewpoint of being cubic and having a (111) plane main orientation, and being capable of taking the overnitrided state (metastable state). In the present embodiment, the nitrogen compound constituting the second base layer 104 is preferably ZrN, Zr₃N₄, HAN, YN, Y₅N₁₄, WN, W₇N₁₂, NbN, and Nb₂N₃, and more preferably ZrN and Zr₃N₄. These nitrogen compounds may be used alone or in combination of two or more thereof.

In the present embodiment, the second base layer 104 preferably has a (111) plane preferential orientation structure that is preferentially oriented in a (111) plane direction, but may not necessarily be (111) plane-preferentially oriented. With the (111) plane preferential orientation structure, lattice matching with the piezoelectric thin film layer 105 is improved, so that the crystalline orientation of the piezoelectric thin film layer 105 can be further improved.

In the present embodiment, it is preferable that the second base layer 104 has a sodium chloride structure, a fluorite structure, or a perovskite structure. With the above structure, preferential orientation in the (111) plane direction is easily achieved, so that crystalline orientation of the outermost layer of the piezoelectric thin film layer 105 can be further improved.

A film thickness of the second base layer is not particularly limited, and is preferably 0.2 nm or more, more preferably 0.4 nm or more, and further preferably 1 nm or more, from the viewpoint of further enhancing the c-axis orientation of the piezoelectric thin film layer. In addition, from the viewpoint of increasing the film formation efficiency and from the viewpoint of preventing a continuous film from being lost due to generation of cracks or the like, the film thickness of the second base layer is preferably 100 nm or less, more preferably 80 nm or less, and further preferably 60 nm or less.

### (Piezoelectric Thin Film Layer)

The piezoelectric thin film layer 105 is a layer having at least one of piezoelectric properties and pyroelectric properties, and is preferably a crystalline thin film having a hexagonal wurtzite structure oriented in a c-axis direction. In the present description, “oriented in a c-axis direction” and “c-axis oriented” mean that a peak intensity ratio of (101) plane/(002) plane in an XRD diffraction pattern of the piezoelectric thin film layer measured by an out-of-plane method is less than 0.3.

The fact that piezoelectric thin film 105 has the hexagonal wurtzite structure can be confirmed by, for example, an X-ray diffraction (XRD) method, an X-ray absorption spectroscopy (XAFS, EXAFS) method, or the like. A crystalline orientation in which piezoelectric properties of the piezoelectric thin film layer 105 having the hexagonal wurtzite structure are exhibited is a direction of the hexagonal wurtzite structure. That is, the piezoelectric thin film layer 105 can achieve excellent piezoelectric properties by a (002) plane of the hexagonal wurtzite structure being oriented (c-axis oriented). Orientation of the (002) plane can be evaluated by, for example, XRD measurement. In a 20 range of 30° to 60°, a half width of a peak of the (002) plane of an AlN crystal appearing at 20=35° to 37° when a 2θ/θ scan is performed is preferably 0.34 or less. From the viewpoint of obtaining higher piezoelectric characteristics, the half width is more preferably 0.32 or less, further preferably 0.30 or less, particularly preferably 0.26 or less, and most preferably 0.25 or less.

As the piezoelectric thin film layer 105, for example, a thin film of aluminum nitride (AlN), ZnO, GaN, or the like is preferably used. Among these, from the viewpoint of manufacturing suitability and the viewpoint of improving the crystallinity of the base layer to be described later, it is particularly preferable that the piezoelectric thin film layer 105 contains AlN, and it is more preferable that the piezoelectric thin film layer 105 has a hexagonal wurtzite structure in which AlN is oriented in the c-axis direction.

A film thickness of the piezoelectric thin film layer 105 is not particularly limited, and is preferably 100 nm or more, more preferably 250 nm or more, further preferably 500 nm or more, and most preferably 1 μm or more, from the viewpoint of ensuring good crystalline orientation and sufficiently ensuring piezoelectric characteristics. On the other hand, the film thickness is preferably 10 μm or less, more preferably 7.5 μm or less, and further preferably 5 μm or less from the viewpoint of allowing crystal growth without generating cracks.

The piezoelectric thin film layer 105 preferably has high smoothness, and preferably has a small arithmetic average roughness (Ra). The arithmetic average roughness (Ra) of a surface of the piezoelectric thin film layer 105 is an arithmetic average roughness of a surface on a side not in contact with the electrode layer 103 or the second base layer 104. The arithmetic average roughness (Ra) is measured by an atomic force microscope (AFM). The arithmetic average roughness (Ra) of the surface of the piezoelectric thin film layer is preferably 3.0 nm or less, more preferably 2.5 nm or less, further preferably 2.0 nm or less, and particularly preferably 1.7 nm or less. In addition, a lower limit of the above arithmetic average roughness (Ra) is not particularly limited, and is preferably 0.1 nm or more, further preferably 0.2 nm or more, and most preferably 0.3 nm or more, from the viewpoint of adhesion during formation of the laminated film.

The piezoelectric laminate according to the present embodiment may include a layer other than the above substrate, electrode layer, base layer, and piezoelectric thin film layer as long as the effect of the present invention is not impaired. For example, an adhesion layer for adhering the substrate and the first base layer may be provided between the substrate and the first base layer. In addition, at least one surface of the substrate may have a thermal oxide film. Further, an upper electrode layer or a protective layer may be provided on the surface of the piezoelectric thin film layer opposite an electrode layer side. Any one of the above layers may be a known layer in the related art.

The piezoelectric laminate according to the present embodiment can be suitably used for a piezoelectric element. The piezoelectric element can be suitably used not only for a component utilizing a piezoelectric effect such as a gyro sensor, a shock sensor, or a microphone, but also for an element utilizing an inverse piezoelectric effect such as an actuator, an inkjet head, a speaker, a buzzer, or a resonator.

### [Method for Manufacturing Piezoelectric Laminate]

The method for manufacturing a piezoelectric laminate according to the present embodiment (hereinafter, also abbreviated as the present manufacturing method) includes: preparing a substrate; and forming a first base layer, an electrode layer, and a piezoelectric thin film layer in this order on at least one surface of the substrate. The piezoelectric thin film preferably contains aluminum nitride, and has a hexagonal wurtzite structure in which the aluminum nitride is oriented in the c-axis direction.

The first base layer contains a nitrogen compound of Group III elements to Group VI elements, and the electrode layer is formed so as to be in contact with the first base layer. After the electrode layer is formed, the second base layer may be formed, and the piezoelectric thin film layer may be further formed.

As the substrate, the first base layer, the electrode layer, the second base layer, and the piezoelectric thin film layer in the present embodiment, the substrate 101, the first base layer 102, the electrode layer 103, the second base layer 104, and the piezoelectric thin film layer 105 described in the above [Structure of Piezoelectric Laminate] can be used, respectively.

The piezoelectric laminate obtained in the present manufacturing method is preferably the piezoelectric laminate 100 described in the above [Structure of Piezoelectric Laminate].

That is, in the piezoelectric laminate obtained by the manufacturing method of the present embodiment, the first base layer and the electrode layer are in contact with each other, and the first base layer contains a nitrogen compound containing at least one element selected from the group consisting of Group III to VI elements.

### (Preparation of Substrate)

As the substrate, for example, the above-described substrate 101 can be used, but a commercially available substrate or a prepared substrate may be used.

### (Formation of Laminated Film)

The laminated film 106 is formed on at least one surface of the substrate 101 prepared above. The laminated film 106 is formed in the order of the first base layer 102, the electrode layer 103, and the piezoelectric thin film layer 105, and any one of these can be formed by adopting, for example, a physical vapor film formation method, a chemical vapor deposition method (CVD method), or the like. Examples of the physical vapor film formation method include a physical vapor deposition method, a PVD method, and a sputtering method. Among those, the sputtering method is still particularly preferable from the viewpoint of being able to control a doping amount in a wide range, and a magnetron sputtering method and a digital sputtering method are particularly preferable. When the laminated film 106 includes the second base layer, the second base layer 104 can be formed after the electrode layer 103 is formed and before the piezoelectric thin film layer 105 is formed. The above method or the like can be adopted for the formation of the second base layer 104.

A substrate temperature during film formation of the laminated film 106 is preferably room temperature to 600° C. or lower, and further preferably 250° C. or lower.

In order to sufficiently exhibit an effect of the base layer, it is preferable to continuously perform film formation without breaking a vacuum state not only during formation of the first base layer 102 but also during forming all of the electrode layer 103, the second base layer 104, and the piezoelectric thin film layer 105. In particular, when the vacuum state is broken during formation of the first base layer 102, the second base layer 104, and the piezoelectric thin film layer 105, oxygen may be mixed as an impurity, and properties of the base layer may not be utilized. In this case, good interface properties cannot be obtained, so that it is preferable to continuously perform the film formation in a vacuum state.

### ((Formation of First Base Layer))

The first base layer 102 may be formed directly on the substrate 101 or may be formed thereon via an adhesion layer. The first base layer contains a nitrogen compound containing at least one element selected from the group consisting of Group III to VI elements, and when the first base layer is formed by a sputtering method, a composition of the nitrogen compound QN_{X}, for example, a value of the nitriding degree x can be adjusted by controlling film formation conditions thereof. Here, Q means Group III to VI elements. The film formation conditions include, for example, a temperature of the substrate during film formation, a film formation pressure, a composition of an introduced gas, a target composition, and a post-heat treatment temperature.

The nitrogen compound constituting the first base layer 102 may contain impurities such as carbon and oxygen inevitably introduced during film formation at a maximum of about 10 at %. In the case where the sputtering method is used, a maximum of about 10 at % of impurities contained in a target is allowed. Examples of the impurities contained in the target containing Group III to VI elements constituting the first base layer 102 include Hf, Ti, Sc, V, Nb, Ta, Cr, Mo, W, O, and C.

When the first base layer 102 is formed, a doping element may be contained. For example, in the case where the piezoelectric thin film layer 105 contains aluminum nitride, the doping element is preferably contained within a range allowing the piezoelectric thin film layer 105 to maintain the hexagonal wurtzite structure. By containing an element such as Sc, Y, Mg, Ca, Sr, Zr, Hf, V, or Nb as the doping element, strain is applied to the piezoelectric thin film layer 105, and the piezoelectric performance is improved. Particularly, the Sc element is preferable for improving the piezoelectric performance, and can be doped up to about 43 at % in this case.

The nitriding degree x of the nitrogen compound in the first base layer 102 can be adjusted by a flow rate of a nitrogen gas during film formation. For example, in a case where the nitriding degree x is adjusted to be in a range of 0<x<2, the flow rate of the nitrogen gas is preferably 20% or more, and particularly preferably 40% or more, in terms of a ratio of {N₂/(Ar+N₂)}. Further, even in a case where the above ratio is 100%, an amount of nitrogen can be adjusted to a larger amount by increasing the film formation pressure by increasing a flow rate of nitrogen, and the nitriding degree x can be set to a value close to 2.

The film formation pressure is preferably 0.05 Pa or more, and more preferably 0.1 Pa or more, from the viewpoint of crystal density and orientation. In addition, the film formation pressure is preferably 10 Pa or less, and more preferably 1 Pa or less.

### ((Formation of Electrode Layer))

The electrode layer 103 is directly formed on the first base layer 102. The electrode layer 103 may be formed of a single layer or two or more layers.

### ((Formation of Second Base Layer))

The formation of the second base layer 104 is not essential, and the second base layer 104 may be formed after the electrode layer 103. In a case where the second base layer 104 is formed, the second base layer 104 contains a nitrogen compound containing at least one element selected from the group consisting of Group III to VI elements, and when the second base layer 104 is formed by a sputtering method, a composition of the nitrogen compound QN_{X} of Group III to VI elements, that is, a value of the nitriding degree x, can be adjusted by controlling film formation conditions thereof. Here, Q means Group III to VI elements. The film formation conditions include, for example, a temperature of the substrate during film formation, a film formation pressure, a composition of an introduced gas, a target composition, and a post-heat treatment temperature.

The nitrogen compound constituting the second base layer 104 may contain impurities such as carbon and oxygen inevitably introduced during film formation at a maximum of about 10 at %. In the case where the sputtering method is used, a maximum of about 10 at % of impurities contained in a target is allowed. That is, the impurities contained in the target include Hf, Ti, Sc, V, Nb, Ta, Cr, Mo, W, O, C, and the like, the target including Group III to VI elements that is a target of the nitrogen compound constituting the first base layer 102, and a target of a material constituting the piezoelectric thin film layer, for example, Al in a case where the material is aluminum nitride AlN.

When the second base layer 104 is formed, a doping element may be contained. For example, in a case where the piezoelectric thin film layer 105 contains aluminum nitride, by containing an element such as Sc, Y, Mg, Ca, Sr, Zr, Hf, V, or Nb as the doping element, strain is applied to the aluminum nitride, and the piezoelectric performance is improved. Particularly, the Sc element is preferable for improving the piezoelectric performance, and can be doped up to about 43 at % in this case.

The nitriding degree x of the nitrogen compound in the second base layer 104 can be adjusted by a flow rate of a nitrogen gas during film formation. For example, in a case where the nitriding degree x is adjusted to be in a range of 0<x<2, the flow rate of the nitrogen gas is preferably 20% or more, and particularly preferably 40% or more, in terms of a ratio of {N₂/(Ar+N₂)}. Further, even in a case where the above ratio is 100%, an amount of nitrogen can be adjusted to a larger amount by increasing the film formation pressure by increasing a flow rate of nitrogen, and the nitriding degree x can be set to a value close to 2.

The film formation pressure is preferably 0.05 Pa or more, and more preferably 0.1 Pa or more, from the viewpoint of crystal density and orientation. In addition, the film formation pressure is preferably 10 Pa or less, and more preferably 1 Pa or less.

### ((Formation of Piezoelectric Thin Film Layer))

The piezoelectric thin film layer 105 may be formed directly on the electrode layer 103, or may be formed directly on the second base layer 104. Further, the piezoelectric thin film layer 105 may be formed on the electrode layer 103 or the second base layer 104 via an adhesion layer.

The piezoelectric thin film layer 105 can be formed by a known method in the related art using a known material in the related art. For example, in a case of a thin film of aluminum nitride having a hexagonal wurtzite structure oriented in the c-axis direction, film formation conditions in a case of film formation by the sputtering method can be, for example, a pressure of 0.05 Pa to 10 Pa, a nitrogen gas partial pressure ratio of 20% to 100%, and a substrate temperature of 25° C. to 200° C.

The nitrogen compound constituting the piezoelectric thin film layer 105 may contain impurities such as carbon and oxygen inevitably introduced during film formation at a maximum of about 10 at %. In the case where the sputtering method is used, a maximum of about 10 at % of impurities contained in a target is allowed. Examples of the impurities contained in the target (for example, Al when the material is AlN) containing the element constituting the piezoelectric thin film layer 105 include Hf, Ti, Sc, V, Nb, Ta, Cr, Mo, W, O, and C.

As described above, the following matters are disclosed in the present description.
1. A piezoelectric laminate, including:
a substrate; and
a laminated film provided on at least one surface of the substrate, in which
the laminated film includes, in order from a substrate side, a first base layer, an electrode layer, and a piezoelectric thin film layer,
the first base layer is in contact with the electrode layer, and
the first base layer contains a nitrogen compound containing at least one element selected from the group consisting of Group III to VI elements.
2. The piezoelectric laminate according to 1, in which
the piezoelectric thin film layer contains aluminum nitride, and
the aluminum nitride has a hexagonal wurtzite structure oriented in a c-axis direction.
3. The piezoelectric laminate according to 1 or 2, in which
the aluminum nitride has a half width at a peak of a (002) plane measured by an X-ray diffraction method being 0.34 or less.
4. The piezoelectric laminate according to any one of 1 to 3, in which
the first base layer has a sodium chloride structure, a fluorite structure, or a perovskite structure.
5. The piezoelectric laminate according to any one of 1 to 4, in which
the first base layer contains a nitrogen compound containing at least one element selected from the group consisting of Group III elements to Group V elements.
6. The piezoelectric laminate according to any one of 1 to 5, in which
the first base layer is a nitrogen compound containing at least one element selected from Zr, Hf, Y, W, and Nb.
7. The piezoelectric laminate according to any one of 1 to 6, in which
the first base layer contains a nitrogen compound represented by a chemical formula QN_{X},
Q in the chemical formula is at least one element selected from the group consisting of Group III to VI elements, and
a nitriding degree represented by x in the chemical formula satisfies 1<x<2.
8. The piezoelectric laminate according to 7, in which
the nitriding degree represented by x in the chemical formula satisfies 1.1<x<1.65.
9. The piezoelectric laminate according to any one of 1 to 8, in which
the first base layer has a thickness of 0.2 nm or more and 100 nm or less.
10. The piezoelectric laminate according to 9, in which
the first base layer has the thickness of 0.4 nm or more and 80 nm or less.
11. The piezoelectric laminate according to any one of 1 to 10, in which
the piezoelectric thin film layer has an arithmetic average roughness (Ra) of 3.0 nm or less.
12. The piezoelectric laminate according to any one of 1 to 11, further including:
a second base layer, in which
the second base layer is in contact with the electrode layer and the piezoelectric thin film layer, and
the second base layer contains a nitrogen compound containing at least one element selected from the group consisting of Group III to VI elements.
13. The piezoelectric laminate according to 12, in which
the second base layer has a thickness of 0.2 nm or more and 40 nm or less.
14. The piezoelectric laminate according to any one of 1 to 13, in which
the piezoelectric thin film layer has a film thickness of 100 nm or more and 10 μm or less.
15. A piezoelectric element including the piezoelectric laminate according to any one of 1 to 14.
16. A method for manufacturing a piezoelectric laminate, the piezoelectric laminate including a substrate and a laminated film provided on at least one surface of the substrate, the method including:
preparing the substrate; and
forming a first base layer, an electrode layer, and a piezoelectric thin film layer on at least one surface of the substrate in this order, in which
the first base layer contains a nitrogen compound containing at least one element selected from the group consisting of Group III to VI elements, and
the electrode layer is formed so as to be in contact with the first base layer.
17. A method for manufacturing a piezoelectric laminate, the piezoelectric laminate including a substrate and a laminated film provided on at least one surface of the substrate, the method including:
preparing the substrate; and
forming a first base layer, an electrode layer, a second base layer, and a piezoelectric thin film layer on at least one surface of the substrate in this order, in which
the first base layer contains a nitrogen compound containing at least one element selected from the group consisting of Group III to VI elements,
the second base layer contains a nitrogen compound containing at least one element selected from the group consisting of Group III to VI elements, and
the electrode layer is formed so as to be in contact with the first base layer.
18. The method for manufacturing a piezoelectric laminate according to 16 or 17, in which
the piezoelectric thin film layer contains aluminum nitride, and
the aluminum nitride has a hexagonal wurtzite structure oriented in a c-axis direction.

### EXAMPLES

Hereinafter, the present invention is specifically described with reference to Examples, but the present invention is not limited thereto.

Examples 1, 2, 5 to 10, 13, 14, 17, 18, 21, and 22 are inventive examples, and Examples 3, 4, 11, 12, 15, 16, 19, 20, 23, and 24 are comparative examples.

### Preparation of Piezoelectric Laminate

### Example 1

A piezoelectric laminate 100 in which an electrode layer 103 and a piezoelectric thin film layer 105 were formed in this order on a substrate 101 and a first base layer 102 was prepared by the following procedures (1) to (4).

### (1) Preparation of Substrate 101

A 25 mm×25 mm×0.625 mm conductive silicon substrate (abbreviated as “conductive Si” in table) was used as the substrate 101.

### (2) Formation of First Base Layer 102

A first base layer 102 was formed on one surface of the substrate 101 by a sputtering method according to the following procedure under the following conditions.

The formation of the first base layer 102 was performed after placing the substrate in a vacuum chamber of a sputtering device, then evacuating the vacuum chamber, and lowering an air pressure to 10⁻³ Pa or less.
Film formation device: vertical in-line sputter (manufactured by ULVAC, Inc.)
Sputtering target material: Zr metal (purity 2N2 (value including Hf), manufactured by Tanaka Kikinzoku Kogyo K.K.)
Introduced gas: 80 sccm of nitrogen gas (purity=99.9% or more)
Film formation pressure: 0.4 Pa
Film thickness: 10 nm
Substrate heating temperature: room temperature

### (3) Formation of Electrode Layer 103

An electrode layer 103 was formed on the first base layer 102 by a sputtering method according to the following procedure.

The formation of the electrode layer 103 was performed under the following conditions after placing a sample on which the first base layer 102 was formed obtained as described above in the vacuum chamber of the sputtering device, then evacuating the vacuum chamber, and lowering the air pressure to 10⁻³ Pa or less, without breaking the vacuum from the formation of the first base layer 102.
Film formation device: vertical in-line sputter (manufactured by ULVAC, Inc.)
Sputtering target material: Ti metal (purity: 3N, manufactured by Kojundo Chemical Laboratory Co., Ltd.)
Introduced gas: 80 sccm of Ar gas (purity=99.9% or more)
Film formation pressure: 0.4 Pa
Film thickness: 100 nm
Substrate heating temperature: room temperature

### (4) Formation of Piezoelectric Thin Film Layer 105

A piezoelectric thin film layer 105 was formed on the electrode layer 103 by a sputtering method according to the following procedure.

The formation of the piezoelectric thin film layer was performed under the following conditions after placing a sample on which the electrode layer 103 was formed obtained as described above in the vacuum chamber of the sputtering device, then evacuating the vacuum chamber, and lowering the air pressure to 10⁻³ Pa or less, without breaking the vacuum from the formation of the electrode layer 103.
Film formation device: vertical in-line sputter (manufactured by ULVAC, Inc.)
Sputtering target material: Al metal (3N), manufactured by Kojundo Chemical Laboratory Co., Ltd.
Introduced gas: 40 sccm of nitrogen gas (purity=99.9% or more)
Film formation pressure: 0.2 Pa
Power density: 7.1 W/cm²
Substrate heating temperature: room temperature
Film thickness: 1,000 nm

In this manner, a piezoelectric laminate 100 was obtained in which a ZrN_{X} film as the first base layer 102, a Ti film as the electrode layer 103, and an aluminum nitride (AlN) film as the piezoelectric thin film layer 105 were formed in this order on the substrate 101.

### Example 2

In Example 2, after the electrode layer 103 was formed, a second base layer 104 was formed by the following procedure, and then the piezoelectric thin film layer 105 was formed. A piezoelectric laminate 100 was prepared in the same manner as in Example 1 except that the second base layer 104 was formed.

The second base layer 104 was formed on a surface of the electrode layer 103 by a sputtering method under the following conditions.

The formation of the second base layer 104 was performed under the following conditions after placing a sample on which the electrode layer 103 was formed obtained as described above in the vacuum chamber of the sputtering device, then evacuating the vacuum chamber, and lowering the air pressure to 10⁻³ Pa or less, without breaking the vacuum from the formation of the electrode layer 103.
Film formation device: vertical in-line sputter (manufactured by ULVAC, Inc.)
Sputtering target material: Zr metal (purity 2N2 (value including Hf), manufactured by Tanaka Kikinzoku Kogyo K.K.)
Introduced gas: 80 sccm of nitrogen gas (purity=99.9% or more)
Film formation pressure: 0.4 Pa
Film thickness: 10 nm
Substrate heating temperature: room temperature

The formation of the piezoelectric thin film layer 105 was performed after lowering the air pressure to 10⁻³ Pa or less without breaking the vacuum from the formation of the second base layer 104.

### Examples 3 and 4

In Examples 3 and 4, piezoelectric laminates 100 were prepared in the same manner to perform film formation as in Examples 1 and 2, respectively, except that the first base layer 102 was not formed.

### Examples 5 to 10

In Examples 5, 6, and 8 to 10, piezoelectric laminates 100 were prepared in the same manner to perform film formation as in Example 1 except that an alkali-free glass was used as the substrate 101 and a film thickness of the first base layer 102 was changed to conditions shown in Table 1.

In Example 7, a piezoelectric laminate 100 was prepared in the same manner to perform film formation as in Example 2 except that an alkali-free glass was used as the substrate 101.

### Examples 11 and 12

In Examples 11 and 12, piezoelectric laminates 100 were prepared in the same manner to perform film formation as in Examples 1 and 2, respectively, except that an alkali-free glass was used as the substrate 101 and the first base layer 102 was not formed.

### Examples 13 and 14

In Examples 13 and 14, piezoelectric laminates 100 were prepared in the same manner to perform film formation as in Examples 1 and 2, respectively, except that an alkali-free glass was used as the substrate 101 and the electrode layer 103 was changed to an ITO film. The ITO film of the electrode layer 103 was formed under the following conditions.
Film formation device: vertical in-line sputter (manufactured by ULVAC, Inc.)
Sputtering target material: ITO (In₂O₃:SnO₂=90 wt %:10 wt %, manufactured by Kinzoku Company, Limited)
Introduced gas: 80 sccm of Ar gas (purity=99.9% or more) and 0.8 sccm of O₂ gas (purity=99.9% or more)
Film formation pressure: 0.5 Pa
Film thickness: 120 nm
Substrate heating temperature: room temperature

### Examples 15 and 16

In Examples 15 and 16, piezoelectric laminates 100 were prepared in the same manner to perform film formation as in Examples 13 and 14, respectively, except that the first base layer 102 was not formed.

### Examples 17 and 18

In Examples 17 and 18, piezoelectric laminates 100 were prepared in the same manner to perform film formation as in Examples 1 and 2, respectively, except that quartz was used for the substrate 101.

### Examples 19 and 20

In Examples 19 and 20, piezoelectric laminates 100 were prepared in the same manner to perform film formation as in Examples 1 and 2, respectively, except that quartz was used for the substrate 101 and the first base layer 102 was not formed.

### Examples 21 and 22

In Examples 21 and 22, piezoelectric laminates 100 were prepared in the same manner to perform film formation as in Examples 13 and 14, respectively, except that quartz was used for the substrate 101.

### Examples 23 and 24

In Examples 23 and 24, piezoelectric laminates 100 were prepared in the same manner to perform film formation as in Examples 13 and 14, respectively, except that quartz was used for the substrate 101 and the first base layer 102 was not formed.

### <Evaluation>

The following measurements and evaluations were performed on each of the obtained piezoelectric laminates 100.

### (Crystalline Orientation of Piezoelectric Thin Film Layer)

For XRD measurement, an X-ray diffraction device (MiniFlex II, manufactured by Rigaku Corporation) was used. A sample was set so as to evaluate diffraction in a direction perpendicular to the substrate, and a 2θ/θ scan was performed with a divergence slit of 1.25°, a scattering slit of 1.25°, and a light receiving slit of 0.3 mm in a 20 range of 30° to 60°.

After background correction was performed, regarding a diffraction intensity of the (002) plane of an AlN crystal appearing at 2θ=35° to 37°, the diffraction intensity ratio of the (002) plane was calculated as a standard value with a case where the first base layer and the second base layer were not provided considered as 1. Tables 1 to 3 show standard values and half widths for the diffraction intensity of the (002) plane.

### (Arithmetic Average Roughness of Surface of Piezoelectric Thin Film Layer)

The arithmetic average roughness (Ra) of the piezoelectric thin film layer was measured by an atomic force microscope (AFM). A definition of the arithmetic average roughness (Ra) conforms to JIS B 0601:2001.

When the arithmetic average roughness (Ra) is 3.0 nm or less, it can be determined that good flatness was obtained, and when the arithmetic average roughness is 1.7 nm or less, it can be determined that better flatness was obtained. Results are shown in “Arithmetic average roughness Ra (nm)” in Tables 1 to 3.
Device: model number: S-Image, manufactured by SII Nano Technology Inc.

### (Nitriding Degree x)

The “nitriding degree x” of the first base layer was calculated based on a “refractive index n” by the following method. Hereinafter, description will be made.

First, for use as a reference, under each of the following conditions of a “film formation condition 1” and a “film formation condition 2”, a 20-nm-thick first base layer 1 and a 20-nm-thick first base layer 2 were formed, respectively.
First base layer 1: film formation condition 1
Power usage: 700 W
Introduced gas: 40 sccm of Ar, and 10 sccm of N₂
Film formation pressure: 0.37 Pa
First base layer 2: film formation condition 2
Power usage: 700 W
Introduced gas: 0 sccm of Ar, and 40 sccm of N₂
Film formation pressure: 0.35 Pa

For the first base layer 1 and the first base layer 2, an element ratio of Zr and N in zirconium nitride constituting a crystallinity-improving layer, that is, a value of the nitriding degree x in ZrN_{X} was determined by Rutherford backscattering spectrometry (RBS) (RBS device, manufactured by Kobe Steel, Ltd.) for quantitative determination. A nitriding degree of the first base layer 1 in Example 1 was 1.6.

TABLE 1

| | | Ex. 1 | Ex. 2 | Ex. 3 | Ex. 4 |
|---|---|---|---|---|---|
| Substrate | | Conductive Si | Conductive Si | Conductive Si | Conductive Si |
| First base layer | Material | ZrN | ZrN | | |
| | Film thickness (nm) | 10 | 10 | 0 | 0 |
| Electrode layer | Material | Ti | Ti | Ti | Ti |
| | Film thickness (nm) | 100 | 100 | 100 | 100 |
| Second base layer | Material | | ZrN | | ZrN |
| | Film thickness (nm) | 0 | 10 | 0 | 10 |
| Piezoelectric thin film | Film formation pressure (Pa) | 0.2 | 0.2 | 0.2 | 0.2 |
| layer (aluminum | Power density (W/cm²) | 7.1 | 7.1 | 7.1 | 7.1 |
| nitride) | Film thickness (nm) | 1,000 | 1,000 | 1,000 | 1,000 |
| Crystalline orientation | 2θ intensity (cps) | 8711104 | 10413347 | 1771857 | 3937450 |
| | 2θ intensity standard value | 4.92 | 5.88 | 1.00 | 2.22 |
| | (002) half width | 0.24 | 0.24 | 0.27 | 0.25 |
| Arithmetic average | Ra (nm) | 1.62 | 1.56 | 1.80 | 1.79 |
| roughness | | | | | |

TABLE 2

| | | Ex. 5 | Ex. 6 | Ex. 7 | Ex. 8 | Ex. 9 | Ex. 10 |
|---|---|---|---|---|---|---|---|
| Substrate | | Alkali-free | Alkali-free | Alkali-free | Alkali-free | Alkali-free | Alkali-free |
| | | glass | glass | glass | glass | glass | glass |
| First base layer | Material | ZrN | ZrN | ZrN | ZrN | ZrN | ZrN |
| | Film thickness | 5 | 10 | 10 | 20 | 50 | 80 |
| | (nm) | | | | | | |
| Electrode layer | Material | Ti | Ti | Ti | Ti | Ti | Ti |
| | Film thickness | 100 | 100 | 100 | 100 | 100 | 100 |
| | (nm) | | | | | | |
| Second base layer | Material | | | ZrN | | | |
| | Film thickness | 0 | 0 | 10 | 0 | 0 | 0 |
| | (nm) | | | | | | |
| Piezoelectric | Film formation | 0.2 | 0.2 | 0.2 | 0.2 | 0.2 | 0.2 |
| thin film layer | pressure (Pa) | | | | | | |
| (aluminum | Power density | 7.1 | 7.1 | 7.1 | 7.1 | 7.1 | 7.1 |
| nitride) | (W/cm²) | | | | | | |
| | Film thickness | 1,000 | 1,000 | 1,000 | 1,000 | 1,000 | 1,000 |
| | (nm) | | | | | | |
| Crystalline | 2θ intensity | 3142645 | 2848833.5 | 5183750.2 | 8716895 | 7461078.7 | 4997955.2 |
| orientation | (cps) | | | | | | |
| | 2θ intensity | 9.33 | 8.46 | 15.39 | 25.88 | 22.16 | 14.84 |
| | standard value | | | | | | |
| | (002) half | 0.26 | 0.26 | 0.25 | 0.26 | 0.26 | 0.26 |
| | width | | | | | | |
| Arithmetic average | Ra (nm) | — | 1.61 | 1.70 | — | — | — |
| roughness | | | | | | | |

| | | Ex. 11 | Ex. 12 | Ex. 13 | Ex. 14 | Ex. 15 | Ex. 16 |
|---|---|---|---|---|---|---|---|
| Substrate | | Alkali-free | Alkali-free | Alkali-free | Alkali-free | Alkali-free | Alkali-free |
| | | glass | glass | glass | glass | glass | glass |
| First base layer | Material | | | ZrN | ZrN | | |
| | Film thickness | 0 | 0 | 10 | 10 | 0 | 0 |
| | (nm) | | | | | | |
| Electrode layer | Material | Ti | Ti | ITO | ITO | ITO | ITO |
| | Film thickness | 100 | 100 | 100 | 100 | 100 | 100 |
| | (nm) | | | | | | |
| Second base layer | Material | | ZrN | | ZrN | | ZrN |
| | Film thickness | 0 | 10 | 0 | 10 | 0 | 10 |
| | (nm) | | | | | | |
| Piezoelectric | Film formation | 0.2 | 0.2 | 0.2 | 0.2 | 0.2 | 0.2 |
| thin film layer | pressure (Pa) | | | | | | |
| (aluminum | Power density | 7.1 | 7.1 | 7.1 | 7.1 | 7.1 | 7.1 |
| nitride) | (W/cm²) | | | | | | |
| | Film thickness | 1,000 | 1,000 | 1,000 | 1,000 | 1,000 | 1,000 |
| | (nm) | | | | | | |
| Crystalline | 2θ intensity | 336767 | 840083 | 870870 | 972138 | 292915 | 798180 |
| orientation | (cps) | | | | | | |
| | 2θ intensity | 1.00 | 2.49 | 2.97 | 3.32 | 1.00 | 2.72 |
| | standard value | | | | | | |
| | (002) half | 0.32 | 0.32 | 0.30 | 0.31 | 0.37 | 0.34 |
| | width | | | | | | |
| Arithmetic average | Ra (nm) | 2.43 | 1.80 | — | — | — | — |
| roughness | | | | | | | |

TABLE 3

| | | Ex. 17 | Ex. 18 | Ex. 19 | Ex. 20 | Ex. 21 | Ex. 22 | Ex. 23 | Ex. 24 |
|---|---|---|---|---|---|---|---|---|---|
| Substrate | | Quartz | Quartz | Quartz | Quartz | Quartz | Quartz | Quartz | Quartz |
| First base layer | Material | ZrN | ZrN | | | ZrN | ZrN | | |
| | Film thickness | 10 | 10 | 0 | 0 | 10 | 10 | 0 | 0 |
| | (nm) | | | | | | | | |
| Electrode layer | Material | Ti | Ti | Ti | Ti | ITO | ITO | ITO | ITO |
| | Film thickness | 100 | 100 | 100 | 100 | 100 | 100 | 100 | 100 |
| | (nm) | | | | | | | | |
| Second base layer | Material | | ZrN | | ZrN | | ZrN | | ZrN |
| | Film thickness | 0 | 10 | 0 | 10 | 0 | 10 | 0 | 10 |
| | (nm) | | | | | | | | |
| Piezoelectric | Film | 0.2 | — | 0.2 | 0.2 | 0.2 | — | 0.2 | 0.2 |
| thin film layer | formation | | | | | | | | |
| (aluminum | pressure (Pa) | | | | | | | | |
| nitride) | Power density | 7.1 | — | 7.1 | 7.1 | 7.1 | — | 7.1 | 7.1 |
| | (W/cm²) | | | | | | | | |
| | Film thickness | 1,000 | 1,000 | 1,000 | 1,000 | 1,000 | 1,000 | 1,000 | 1,000 |
| | (nm) | | | | | | | | |
| Crystalline | 2θ intensity | 9394280.4 | 9509690.5 | 1448338.4 | 4582558.6 | 1108943.4 | 781922 | 295948 | 891212 |
| orientation | (cps) | | | | | | | | |
| | 2θ intensity | 6.49 | 6.57 | 1.00 | 3.16 | 3.75 | 2.64 | 1.00 | 3.01 |
| | standard value | | | | | | | | |
| | (002) half | 0.23 | 0.24 | 0.28 | 0.27 | 0.32 | 0.34 | 0.38 | 0.40 |
| | width | | | | | | | | |
| Arithmetic | Ra (nm) | — | — | — | — | — | — | — | — |
| average roughness | | | | | | | | | |

### (Effect of First Base Layer)

In Table 1, when Example 1 is compared with Example 3 and Example 2 is compared with Example 4, it is understood that the crystalline orientation is increased when the first base layer is provided. Further, it is understood that a value of the arithmetic average roughness Ra representing a surface flatness is reduced when the first base layer is provided.

In Table 2, the same tendency is understood also when Examples 5 to 10 are compared with Examples 11 to 12. Further, the same tendency is understood also when Examples 13 and 14 are compared with Examples 15 and 16.

In Table 3, the same tendency is understood also when Examples 17 and 18 are compared with Examples 19 and 20. Further, the same tendency is understood also when Examples 21 and 22 are compared with Examples 23 and 24.

Examples 5 to 10 in Table 2 show results of the crystalline orientation and the arithmetic average roughness Ra of the piezoelectric thin film layer made of AlN having a film thickness of 1,000 nm, the crystalline orientation being measured using the XRD measurement, when a film thickness of the ZrN_{X} film of the first base layer is changed from 5 nm to 80 nm.

From results of Tables 1 to 3, it is understood that a piezoelectric laminate is obtained in which the film thickness of the first base layer is 5 nm or more and 80 nm or less, the arithmetic average roughness Ra is 1.7 nm or less, the half width of a peak of the (002) plane of the AlN crystal is 0.34 or less, and a surface shape is good and the orientation is excellent.

From the results of Tables 1 to 3, it was confirmed that the orientation and the surface shape of the piezoelectric thin film layer were improved by providing the first base layer regardless of types of the substrate and the electrode layer.

Note that, the present application is based on a Japanese Patent Application No. 2023-187764 filed on Nov. 1, 2023, contents of which are incorporated herein by reference.

### REFERENCE SIGNS LIST

100: piezoelectric laminate
101: substrate
102: first base layer
103: electrode layer
104: second base layer
105: piezoelectric thin film layer
106: laminated film

1. A piezoelectric laminate, comprising:
a substrate; and
a laminated film provided on at least one surface of the substrate, wherein
the laminated film comprises, in order from a substrate side, a first base layer, an electrode layer, and a piezoelectric thin film layer,
the first base layer is in contact with the electrode layer, and
the first base layer contains a nitrogen compound containing at least one element selected from the group consisting of Group III to VI elements.

2. The piezoelectric laminate according to claim 1, wherein
the piezoelectric thin film layer contains aluminum nitride, and
the aluminum nitride has a hexagonal wurtzite structure oriented in a c-axis direction.

3. The piezoelectric laminate according to claim 2, wherein
the aluminum nitride has a half width at a peak of a (002) plane measured by an X-ray diffraction method being 0.34 or less.

4. The piezoelectric laminate according to claim 1, wherein
the first base layer has a sodium chloride structure, a fluorite structure, or a perovskite structure.

5. The piezoelectric laminate according to claim 1, wherein
the first base layer contains a nitrogen compound containing at least one element selected from the group consisting of Group III to V elements.

6. The piezoelectric laminate according to claim 1, wherein
the first base layer is a nitrogen compound containing at least one element selected from the group consisting of Zr, Hf, Y, W, and Nb.

7. The piezoelectric laminate according to claim 1, wherein
the first base layer contains a nitrogen compound represented by a chemical formula QN_{X},
Q in the chemical formula is at least one element selected from the group consisting of Group III to VI elements, and
a nitriding degree represented by x in the chemical formula satisfies 1<x<2.

8. The piezoelectric laminate according to claim 7, wherein
the nitriding degree represented by x in the chemical formula satisfies 1.1<x<1.65.

9. The piezoelectric laminate according to claim 1, wherein
the first base layer has a thickness of 0.2 nm or more and 100 nm or less.

10. The piezoelectric laminate according to claim 9, wherein
the first base layer has the thickness of 0.4 nm or more and 80 nm or less.

11. The piezoelectric laminate according to claim 1, wherein
the piezoelectric thin film layer has an arithmetic average roughness (Ra) of 3.0 nm or less.

12. The piezoelectric laminate according to claim 1, further comprising:
a second base layer, wherein
the second base layer is in contact with the electrode layer and the piezoelectric thin film layer, and
the second base layer contains a nitrogen compound containing at least one element selected from the group consisting of Group III to VI elements.

13. The piezoelectric laminate according to claim 12, wherein
the second base layer has a thickness of 0.2 nm or more and 40 nm or less.

14. The piezoelectric laminate according to claim 1, wherein
the piezoelectric thin film layer has a film thickness of 100 nm or more and 10 μm or less.

15. A piezoelectric element comprising the piezoelectric laminate according to claim 1.

16. A method for manufacturing a piezoelectric laminate, the piezoelectric laminate including a substrate and a laminated film provided on at least one surface of the substrate, the method comprising:
preparing the substrate; and
forming a first base layer, an electrode layer, and a piezoelectric thin film layer on at least one surface of the substrate in this order, wherein
the first base layer contains a nitrogen compound containing at least one element selected from the group consisting of Group III to VI elements, and
the electrode layer is formed so as to be in contact with the first base layer.

17. A method for manufacturing a piezoelectric laminate, the piezoelectric laminate including a substrate and a laminated film provided on at least one surface of the substrate, the method comprising:
preparing the substrate; and
forming a first base layer, an electrode layer, a second base layer, and a piezoelectric thin film layer on at least one surface of the substrate in this order, wherein
the first base layer contains a nitrogen compound containing at least one element selected from the group consisting of Group III to VI elements,
the second base layer contains a nitrogen compound containing at least one element selected from the group consisting of Group III to VI elements, and
the electrode layer is formed so as to be in contact with the first base layer.

18. The method for manufacturing a piezoelectric laminate according to claim 16, wherein
the piezoelectric thin film layer contains aluminum nitride, and
the aluminum nitride has a hexagonal wurtzite structure oriented in a c-axis direction.

19. The method for manufacturing a piezoelectric laminate according to claim 17, wherein
the piezoelectric thin film layer contains aluminum nitride, and
the aluminum nitride has a hexagonal wurtzite structure oriented in a c-axis direction.
